(19) United States
(12) Patent Application Publication
(10) Pub. No.: US 2013/0321997 A1
(43) Pub. Date: Dec. 5, 2013

(54) SERVER

(71) Applicant: Shu-Ni YI, Shenzhen City (CN)

(72) Inventor: Shu-Ni YI, Shenzhen City (CN)

(73) Assignees: HON HAI PRECISION INDUSTRY CO., LTD., Tu-Cheng (TW); HONG FU JIN PRECISION INDUSTRY(ShenZhen) CO., LTD., Shenzhen City (CN)

(21) Appl. No.: 13/531,408

(22) Filed: Jun. 22, 2012

(30) Foreign Application Priority Data
May 30, 2012 (CN) 201210172783.2

(51) Int. Cl. H05K 7/00

(52) U.S. Cl. 361/679.02

(57) ABSTRACT

A server includes a chassis, a switch cable received in the chassis, and a power cord located out of the chassis. Interfaces for connecting data lines are attached to a front plate of the chassis. A power interface is attached to a rear plate of the chassis. The switch cable includes a first connector and a second connector at opposite ends of the switch cable. The first connector is connected to the power interface. The second connector is fastened to the front plate of the chassis. The power cord is connected to the second connector.

### BACKGROUND

1. Technical Field

The present disclosure relates to a server.

2. Description of Related Art

In a data center, a number of server cabinets are generally placed back-to-back, so the space is narrow at rear ends of the cabinets. A plurality of data cables and power cords are generally connected to rear ends of the servers in the cabinets. It is inconvenient to manipulate the cables at the narrow rear ends of the cabinets.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of a server, wherein the server includes a positioning member.

FIGS. 2 and 3 are partially enlarged views of FIG. 1.

FIG. 4 is a partially sectional view of FIG. 2.

FIG. 5 is an enlarged, isometric view of the positioning member of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

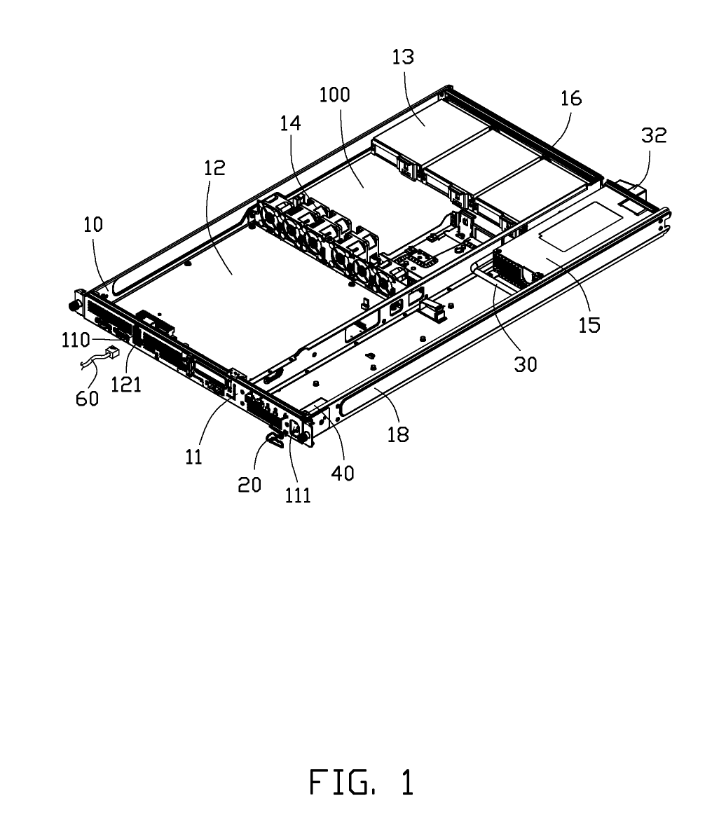

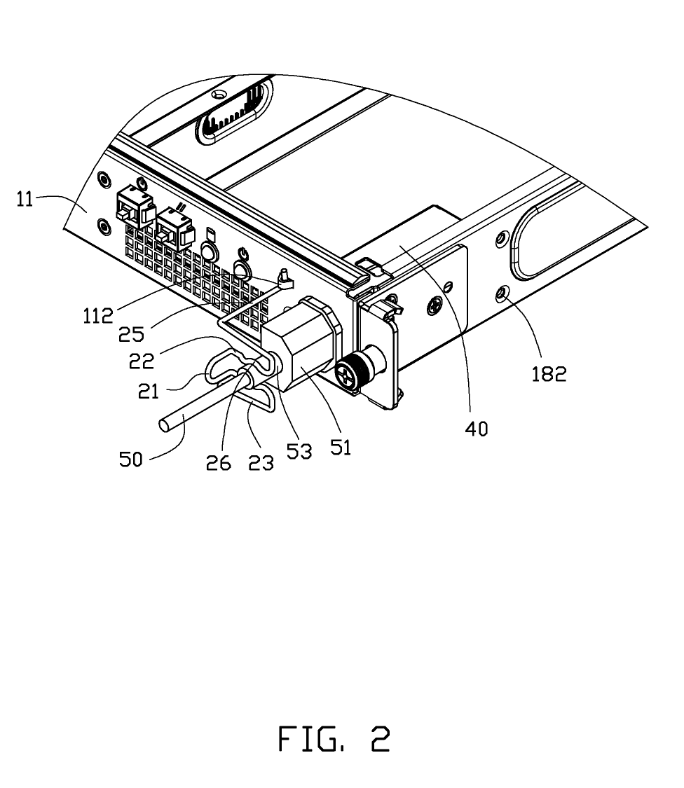

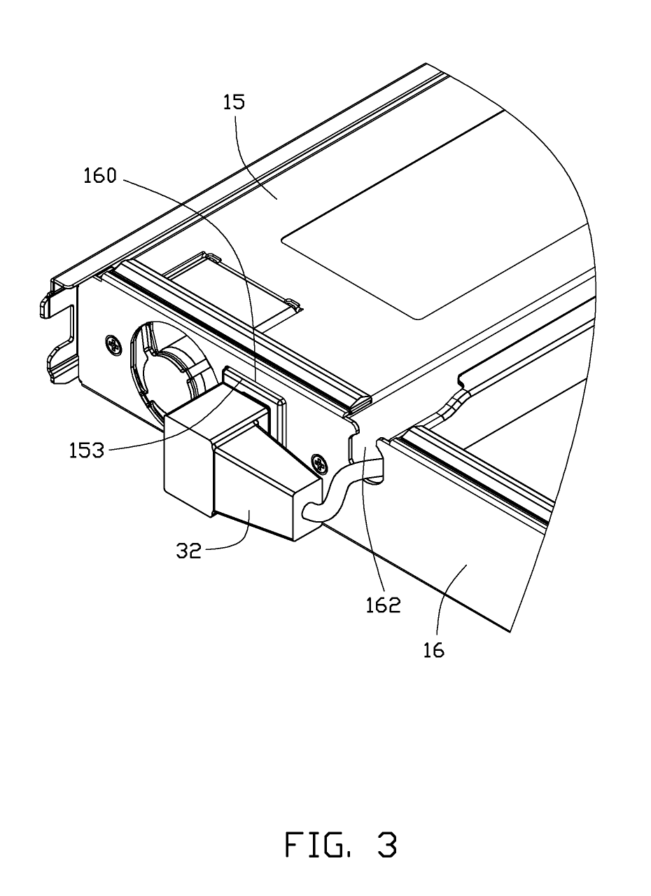

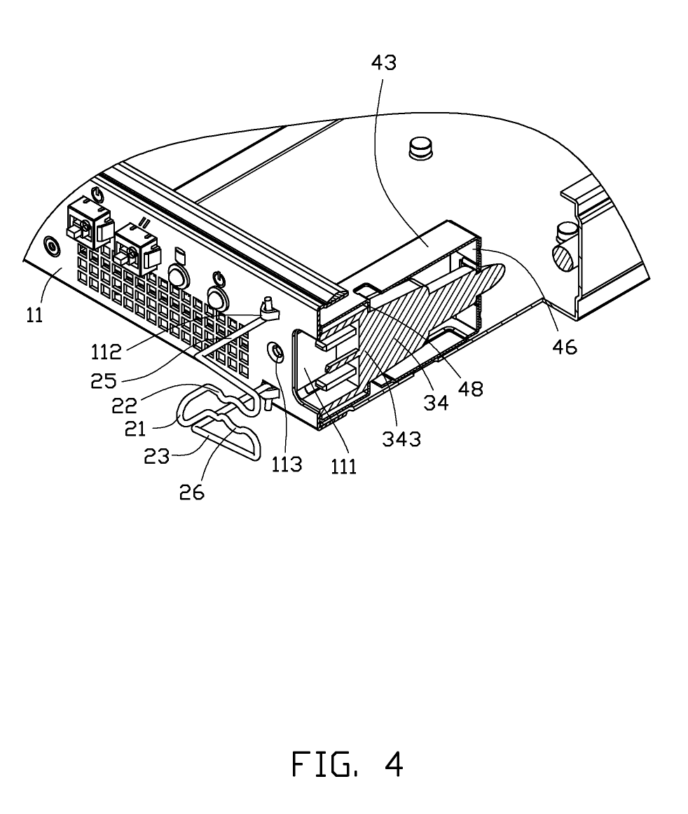

FIGS. 1-4 show an exemplary embodiment of a server. The server includes a chassis 10, a clip 20, a switch cable 30, a positioning member 40, and a power cord 50 located out of the chassis 10.

The chassis 10 includes a front plate 11, a rear plate 16, and a side plate 18 connected between corresponding ends of the front plate 11 and the rear plate 16. The front plate 11, the rear plate 16, and the side plate 18 cooperatively bound a receiving space 100. A motherboard 12 is mounted in the receiving space 100, adjacent to the front plate 11.

The front plate 11 defines a plurality of openings 110, facing the motherboard 12. Data interfaces 121 of the motherboard 12 for connecting data cables 60, such as universal serial bus (USB) interfaces and Registered Jack-45 (RJ-45) interfaces, are attached to the front plate 11 and exposed through the openings 110. A plurality of data storage devices 13 is mounted in the receiving space 100, adjacent to the rear plate 16. A plurality of system fans 14 is mounted in a middle of the receiving space 100, between the motherboard 12 and the data storage devices 13. A power supply 15 is mounted in the receiving space 100, near the rear plate 16 and the side plate 18. The power supply 15 includes a power interface 153 attached to and exposed through the rear plate 16 through an opening 160 defined in the rear plate 16. An opening 111 is defined in the front plate 11, adjacent to the side plate 18. Two substantially V-shaped hooking tabs 112 are formed on an outer surface of the front plate 11, adjacent to a left side of the opening 111 opposite to the side plate 18. A through hole 113 is defined in the front plate 11, between the hooking tabs 112 and the opening 111.

Two through holes 182 are defined in the side plate 18, adjacent to the front plate 11. An opening 162 is defined in the rear plate 16, extending through a top of the rear plate 16 and adjacent to the side plate 18.

The clip 20 includes a substantially U-shaped operation portion 21 with two distal ends facing the front plate 11, two clamping arms 22 extending toward the side plate 18 from the distal ends of the operation portion 21, two L-shaped extension arms 23 respectively extending up and down firstly and then extending toward the operation portion 21 from distal ends of the clamping arms 22 opposite to the operation portion 21, and two L-shaped hooks 25 extending toward the front plate 11 firstly and then respectively extending up and down from distal ends of the extension arms 23 opposite to the clamping arms 22. An arc-shaped clamping portion 26 is formed by curving a middle of each clamping arm 22 away from the other clamping arm 22.

A plug 51 electrically connected to the power cord 50 extends through the opening 111. A tube portion 53 extends from a front end of the plug 51 opposite to the opening 111 to fit about a part of the power cord 50 connected to the plug 51.

The switch cable 30 is received in the receiving space 100, and includes a first connector 32 and a second connector 34 formed at opposite ends of the switch cable 30. The second connector 34 includes a connection portion 343 to connect the plug 51. The connection portion 343 is thicker than other portions of the second connector 34.

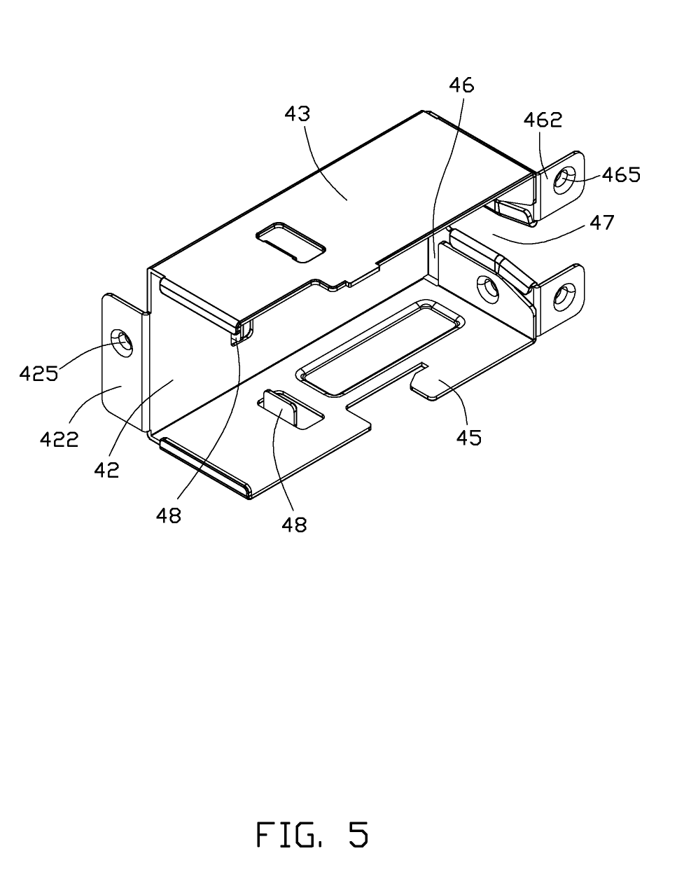

FIG. 5 shows the positioning member 40 including a sidewall 42, a top wall 43 and a bottom wall 45 respectively extending from top and bottom sides of the sidewall 42 in a substantially perpendicular manner, and an end wall 46 perpendicularly extending from a rear end of the sidewall 42. A notch 47 is defined in the end wall 46, extending through a first side of the end wall 46 opposite to the sidewall 42. Two fastening tabs 462 perpendicularly extend back from the first side of the end wall 46, respectively above and below the notch 47. A fastening hole 465 is defined in each fastening tab 462. A fastening tab 422 perpendicularly extends out from a front end of the sidewall 42 away from the end wall 46. A fastening hole 425 is defined in the fastening tab 422. Three block tabs 48 respectively extend in from the top wall 43, the bottom wall 45, and the sidewall 42 in a substantially perpendicular manner The block tabs 48 are coplanar.

In assembly, the switch cable 30 near the first connector 32 extends through the opening 162, to allow the first connector 32 to be connected to the power interface 153. The switch cable 30 near the second connector 34 extends through the notch 47, to allow the second connector 34 to be received in the positioning member 40. The second connector 34 and the positioning member 40 are manipulated, to allow the fastening tabs 462 to abut against an inner side of the side plate 18 and allow the fastening tab 422 to abut against an inner side of the front plate 11. The second connector 34 aligns with the opening 111. Three screws extend through the through holes 113 and 182, and engage in the fastening holes 425 and 465. A rear surface of the connection portion 343 abuts against the block tabs 48, and a front surface of the connection portion 343 abuts against the front plate 11. Therefore, the second connector 34 is fastened by the positioning member 40 and the chassis 10.

The hooks 25 are deformed toward each other, to hook the hooking tabs 112, thereby rotatably connecting the clip 20 to the front plate 11. The operation portion 21 is manipulated, to allow the clip 20 to rotate away from the side plate 18. The plug 51 extends through the opening 111 to be connected to the second connector 34. The clip 20 is rotated toward the side plate 18. The tube portion 53 extends through a space between the clamping arms 22, to be sandwiched between the clamping portions 26, to prevent the power cord 50 from disengaging from the second connector 34.

The data cables 60 connected to the data interfaces 121 and the power cord 50 connected to the second connector 34 are all located in front of the chassis 10. Therefore, the data cables 60 and the power cord 50 can be manipulated in front of the server cabinet holding the server.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A server, comprising:
a chassis comprising a front plate, a rear plate opposite to the front plate, the front plate and the rear plate together bounding a receiving space for receiving a motherboard with a plurality of data interfaces and a power supply with a power interface, the front plate defining a plurality of first openings through which the data interfaces of the motherboard are exposed and a second opening; and
a switch cable received in the receiving space, and comprising a first connector connected to the power interface, and a second connector fastened to the front plate of the chassis and exposed through the second opening.

2. The server of claim 1, wherein the chassis further comprises a side plate connected between corresponding ends of the front plate and the rear plate, the rear plate defines a third opening through which the power cable of the power supply is exposed and a fourth opening, the switch cable near the first connector extends through the fourth opening, to allow the first connector to be connected to the power interface.

3. The server of claim 2, wherein a positioning member is fastened to the chassis, for receiving the second connector, the second connector includes a connection portion in a front of the second connector, a plurality of block tabs extends in from the positioning member to block a rear side of the connection portion.

4. The server of claim 3, wherein the positioning member comprises a sidewall, a top wall and a bottom wall respectively extending from top and bottom sides of the sidewall in a substantially perpendicular manner, and an end wall extending from a rear end of the sidewall in a substantially perpendicular manner, the block tabs extend from the top wall, the bottom wall, and the sidewall, the end wall defines a notch for the switch cable near the second connector extending through.

5. The server of claim 4, wherein a first fastening tab extends from a side of the end wall opposite to the sidewall to be fastened to the side plate, a second fastening tab extends from a front end of the sidewall opposite to the end wall to be fastened to the front plate.

6. The server of claim 1, further comprising a clip rotatably connected to the front plate to clip a power cord connected to the power interface of the power supply.

7. The server of claim 6, wherein two V-shaped hooking tabs are formed on an outer surface of the front plate, adjacent to the second connector of the switch cable, the clip comprises a substantially U-shaped operation portion, two clamping arms extending toward the second connector from distal ends of the operation portion, two L-shaped extension arms extending up and down firstly and then away from the second connector from ends of the clamping arms opposite to the operation portion, and two L-shaped hooks extending back firstly and then respectively up and down from distal ends of the extension arms, an arc-shaped clamping portion is curved from each clamping arm away from the other clamping arm, the hooks hook the corresponding hooking tabs, the clip is rotatable about the hooks, the clamping portions are operable to sandwich the power cord.

8. A server, comprising:
a chassis comprising a front plate, a rear plate opposite to the front plate, a motherboard accommodated between the front plate and the rear plate and adjacent to the front plate, and a power supply accommodated between the front plate and the rear plate and adjacent to the rear plate, a plurality of data interfaces of the motherboard for connecting data cables attached to and exposed through the front plate, a power interface of the power supply attached to and exposed through the rear plate; and
a switch cable received between the front plate and the rear plate, and comprising a first connector connected to the power interface and a second connector fastened to and exposed through the front plate of the chassis; and
a power cord comprising a plug extending through the front plate of the chassis to be connected to the second connector.

9. The server of claim 8, wherein the chassis further comprises a side plate connected between corresponding ends of the front plate and the rear plate, the rear plate defines a first opening through which the power interface of the power supply is exposed, and a second opening, the switch cable near the first connector extends through the second opening, to allow the first connector to be connected to the power interface.

10. The server of claim 9, wherein a positioning member is fastened to the chassis, for receiving the second connector, the second connector includes a connection portion abutting against an inner surface of the front plate with a front side, a plurality of block tabs extends in from the positioning member to block a rear side of the connection portion.

11. The server of claim 9, wherein the positioning member comprises a sidewall, a top wall and a bottom wall respectively extending from top and bottom sides of the sidewall, and an end wall extending from a rear end of the sidewall, the block tabs extend in from the top wall, the bottom wall, and the sidewall, the end wall defines a notch for the switch cable near the second connector extending through.

12. The server of claim 11, wherein a first fastening tab extends from a side of the end wall away from the sidewall and is fastened to the side plate, a second fastening tab extends from a front end of the sidewall away from the end wall and is fastened to the front plate.

13. The server of claim 9, further comprising a clip rotatably connected to the front plate to clip the power cord.

14. The server of claim 13, wherein two hooking tabs are formed on an outer surface of the front plate, adjacent to the side plate, the clip comprises a substantially U-shaped operation portion, two clamping arms extending toward the side plate from distal ends of the operation portion, two substantially L-shaped extension arms extending up and down firstly and then extending away from the side plate from distal ends of the clamping arms, and two substantially L-shaped hooks extending back firstly and then respectively extending up and down from distal ends of the extension arms, an arc-shaped clamping portion is curved from each clamping arm away from the other clamping arm, the hooks hook the corresponding hooking tabs, the power cord is clipped between the clamping portions.

15. The server of claim 14, wherein the power cord comprises a plug connected to the second connector and a tube adjoining the plug and fitting about a portion of the power cord connected to the plug, the tube is clipped between the clamping portions.
